(19) United States
(12) Patent Application Publication
(10) Pub. No.: US 2026/0059656 A1
(43) Pub. Date: Feb. 26, 2026

(54) HEAT SINK-INTEGRATED SUBSTRATE FOR POWER MODULE AND METHOD FOR PRODUCING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 19/111,997

(22) PCT Filed: Sep. 7, 2023
(86) PCT No.: PCT/KR2023/013400

§ 371 Date: Mar. 14, 2025

(30) Foreign Application Priority Data
Sep. 16, 2022 (KR) 10-2022-0116830

(51) Int. Cl. H05K 1/02; H05K 1/03; H05K 1/09; H05K 3/00; H05K 3/12

(52) U.S. Cl. CPC H05K 1/0272; H05K 1/0306; H05K 1/092; H05K 3/0014; H05K 3/1216; H05K 2201/032; H05K 2201/064

(57) ABSTRACT

A method of manufacturing a heat sink-integrated power module substrate according to an embodiment of the present disclosure may include preparing a ceramic heat sink, forming a pattern of a conductive material on a top surface of the ceramic heat sink, and forming an electrode pattern by firing the conductive material. Here, the pattern of the conductive material may be formed on the top surface of the ceramic heat sink using screen printing.

### TECHNICAL FIELD

The present disclosure relates generally to a heat sink-integrated power module substrate and a method of manufacturing the heat sink-integrated power module substrate, and more particularly to a heat sink-integrated power module substrate in which an electrode pattern is formed in a ceramic heat sink and a method of manufacturing the heat sink-integrated power module substrate.

### BACKGROUND ART

An electric vehicle requires an inverter that converts a Direct Current (DC) voltage provided by a high-voltage battery into a 3-phase Alternating Current (AC) voltage required to drive a motor.

A power module for controlling the high voltage of a driving battery to a state suitable for the motor and supplying the controlled voltage is assembled with the inverter. The power module includes a semiconductor chip for power conversion, and the semiconductor chip generates high-temperature heat due to a high voltage and high current operation. When such heat persists, a problem arises in that the semiconductor chip is degraded and the performance of the power module is deteriorated. In order to solve this problem, a heat sink is bonded to at least one surface of a ceramic or metal substrate to prevent the degradation of semiconductor chips caused by heat.

Generally, a heat sink is made of a metal material having high thermal conductivity, such as copper or aluminum, and even such a metal heat sink has a limitation in heat dissipation, thus rapidly decreasing cooling efficiency and causing warping to lead to failures when heat exceeding the limitation is generated. Further, a problem arises in that warping or the like attributable to heat occurs even in a substrate on which a semiconductor chip is mounted, thus degrading characteristics.

The matters described in the above background art are intended to aid in understanding the background of the disclosure and may include aspects that are not part of the disclosed prior art.

### SUMMARY OF INVENTION

### Technical Problem

The present disclosure has been made keeping in mind the above problems, and an object of the present disclosure is to provide a heat sink-integrated power module substrate and a method of manufacturing the heat sink-integrated power module substrate, which are configured to effectively dissipate heat generated in semiconductor chips.

### Solution to Problem

To achieve the above object, a method of manufacturing a heat sink-integrated power module substrate according to an embodiment of the present disclosure includes preparing a ceramic heat sink, forming a pattern of a conductive material on a top surface of the ceramic heat sink, and forming an electrode pattern by firing the conductive material.

The forming of the pattern of the conductive material may include arranging a screen mask on the top surface of the ceramic heat sink, and printing the pattern of the conductive material on the top surface of the ceramic heat sink through the screen mask.

In the printing of the pattern of the conductive material, the conductive material may be conductive paste containing at least one of Ag, Cu, an Ag alloy, a Cu alloy, W, Mo, or MoW.

The printing of the pattern of the conductive material may include putting the conductive paste on the screen mask, bringing a squeegee into contact with the screen mask, and moving the squeegee on the screen mask, and in the moving, the conductive paste may be applied to the top surface of the ceramic heat sink after passing through an open pattern region of the screen mask. Here, the screen mask may have a structure in which the pattern region is open in a shape of a mesh and a remaining region is closed.

The forming of the electrode pattern may include forming the electrode pattern by firing the conductive material at a temperature ranging from 350° C. to 450° C.

In the preparing of the ceramic heat sink, the ceramic heat sink may be manufactured using any one method of injection molding or die casting.

In the preparing of the ceramic heat sink, the ceramic heat sink may include a flat portion in which the electrode pattern is formed on a top surface thereof and a plurality of protrusions formed on a bottom surface of the flat portion to protrude at intervals and provided to contact liquid coolant.

In the preparing of the ceramic heat sink, the ceramic heat sink may be formed of any one of AlN, Si₃N₄, Zirconia Toughed Alumina (ZTA), Al₂O₃, or SiC.

A heat sink-integrated power module substrate according to an embodiment of the present disclosure includes a ceramic heat sink including a flat portion and a plurality of protrusions that are formed on a bottom surface of the flat portion to protrude at intervals and that contact liquid coolant, and an electrode pattern formed on a top surface of the flat portion, wherein the electrode pattern is generated by forming a pattern of a conductive material on the top surface of the flat portion and then firing the conductive material. The plurality of protrusions may be arranged in an external coolant circulation unit, and the liquid coolant circulating through the coolant circulation unit may perform heat exchange with the plurality of protrusions.

The pattern of the conductive material may be formed on the top surface of the flat portion using a screen-printing method. The conductive material may be conductive paste containing at least one of Ag, Cu, an Ag alloy, a Cu alloy, W, Mo, or MoW.

The ceramic heat sink may be manufactured using any one method of injection molding or die casting. The ceramic heat sink may be formed of any one of AlN, Si₃N₄, Zirconia Toughed Alumina (ZTA), Al₂O₃, or SiC.

### Advantageous Effects of Invention

The present disclosure is advantageous in that a power module substrate is formed by directly printing a conductive material on the top surface of a ceramic heat sink, thereby minimizing a process, and maximizing heat dissipation effect while implementing lightweight and small-sized structures.

Further, since, in the present disclosure, electrode patterns are formed using a screen printing method, the electrode patterns may be precisely formed, various patterns may be flexibly implemented, a stable bonding state may be maintained even with thin patterns, and wire bondability may be excellent during wire connections.

Furthermore, since, in the present disclosure, a ceramic heat sink is formed of any one of AlN, Si₃N₄, Zirconia Toughed Alumina (ZTA), Al₂O₃, and SiC, warping hardly occurs even in a high-temperature environment due to a low thermal expansion coefficient, and heat dissipation performance may be enhanced.

Furthermore, in the present disclosure, even if high-temperature heat is generated from a semiconductor chip, continuously circulating liquid coolant directly contacts a ceramic heat sink to cool the ceramic heat sink, thereby maximizing heat dissipation effect.

### BRIEF DESCRIPTION OF DRAWINGS

FIG. 1 is a top perspective view illustrating a heat sink-integrated power module substrate according to an embodiment of the present disclosure.

FIG. 2 is a bottom perspective view illustrating a heat sink-integrated power module substrate according to an embodiment of the present disclosure.

FIG. 3 is a bottom perspective view illustrating a modified example of a plurality of protrusions on a heat sink-integrated power module substrate according to an embodiment of the present disclosure.

FIG. 4 is a conceptual view illustrating a configuration in which a heat sink-integrated power module substrate is mounted in a coolant circulation unit and a circulation driving unit is connected to the coolant circulation unit according to an embodiment of the present disclosure.

FIG. 5 is a flowchart illustrating a method of manufacturing a heat sink-integrated power module substrate according to an embodiment of the present disclosure.

FIG. 6 is a view for describing a screen printing process for forming an electrode pattern.

### DESCRIPTION OF EMBODIMENTS

Hereinafter, exemplary embodiments of the present disclosure will be described in detail with reference to the attached drawings.

The embodiments are provided to more completely describe the present disclosure to those skilled in the art, the following embodiments may be modified in various different forms, and the scope of the present disclosure is limited to the following embodiments. Rather, these embodiments are provided to further enrich and complete the present disclosure and to fully convey the spirit of the present disclosure.

Terms used in the present specification are intended to describe specific embodiments and are not intended to limit the present disclosure. In addition, in the present specification, singular forms may include plural forms unless the context clearly indicates otherwise.

In the description of embodiments, when each layer (film), region, pattern, or structure is described as being formed “on” or “under” a substrate, each layer (film), region, pad, or pattern, the terms “on” and “under” encompass “directly” formed structures or “indirectly” formed structures with the interposition of another layer. In addition, the reference for “on” or “under” with respect to each layer is, in principle, based on the drawings.

Drawings are merely intended to help understanding of the spirit of the present disclosure, and should not be construed as limiting the scope of the present disclosure. Furthermore, the relative thickness, length, or size depicted in the drawings may be exaggerated for the convenience and clarity of description.

Hereinafter, embodiments of the present disclosure will be described in detail with reference to the attached drawings.

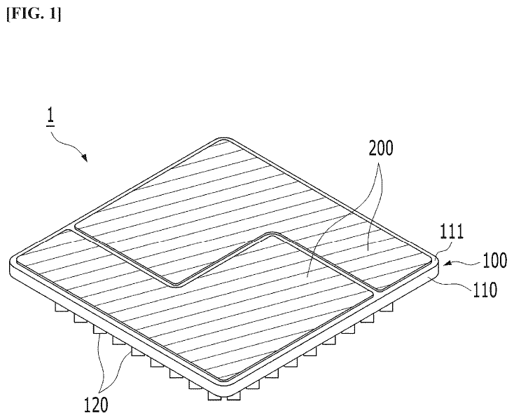

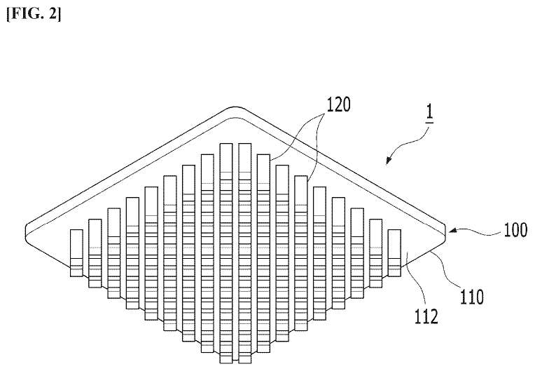

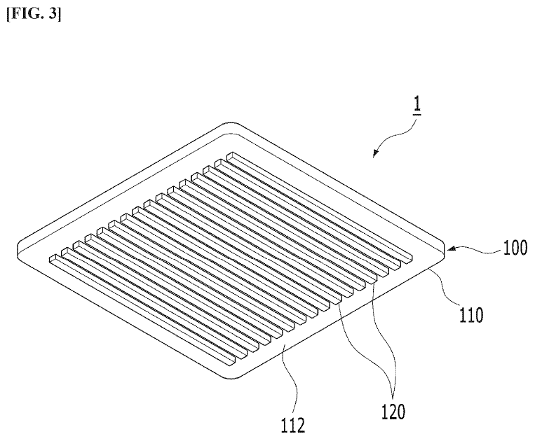

FIG. 1 is a top perspective view illustrating a heat sink-integrated power module substrate according to an embodiment of the present disclosure, FIG. 2 is a bottom perspective view illustrating a heat sink-integrated power module substrate according to an embodiment of the present disclosure, and FIG. 3 is a bottom perspective view illustrating a modified example of a plurality of protrusions on a heat sink-integrated power module substrate according to an embodiment of the present disclosure.

As illustrated in FIGS. 1 to 3, a heat sink-integrated power module substrate 1 according to an embodiment of the present disclosure may include a ceramic heat sink 100 and an electrode pattern 200.

The ceramic heat sink 100 may be formed of any one of Aluminum Nitride (AlN), Si₃N₄, Zirconia Toughed Alumina (ZTA), Al₂O₃, and SiC. In case that the ceramic heat sink 100 is formed of a metal material such as Cu, the coefficient of thermal expansion of Cu is 17 ppm/K, and thus warping caused by thermal expansion occurs when the ceramic heat sink is applied to a power module in which heat of 200° C. or higher is generated, thus decreasing a heat dissipation function, and resulting in a short circuit at the time of connecting the ceramic heat sink to a lead frame or the like through a wire.

On the other hand, when the ceramic heat sink 100 is formed of any one of AlN, Si₃N₄, Zirconia Toughed Alumina (ZTA), Al₂O₃, and SiC, warping hardly occurs even in a high-temperature environment of 600° C. or higher, thus enhancing heat dissipation performance. In addition, since AlN has a thermal conductivity of 150 W/m·K or more and Si₃N₄ has a thermal conductivity of 80 W/m·K or more, they may be effective in heat dissipation when used for the heat sink.

The ceramic heat sink 100 may be manufactured by any one method of injection molding (ceramic injection molding) and die casting. Injection molding is a construction method of injecting a heated ceramic material into a cavity in a closed mold and cooling the ceramic material within the mold, thus forming a molded product corresponding to the mold cavity. Further, the die-casting construction method is a method of injecting a ceramic material into a mold and then obtaining a casting identical to the mold, thus enabling the mass production of molded products with complex shapes. After the injection molding or die casting, the ceramic heat sink 100 may be manufactured through a heat treatment process and, in addition, the ceramic heat sink 100 may also be formed using a construction method such as extrusion, cutting processing, or press processing.

The ceramic heat sink 100 may include a flat portion 110 and a plurality of protrusions 120. The flat portion 110 may be a portion in which electrode patterns 200 are formed on a top surface 111 thereof to directly contact the electrode patterns 200, and may be provided in the form of a flat panel having a large area so as to facilitate heat transfer. The plurality of protrusions 120 may be formed on a bottom surface 112 of the flat portion 110 to protrude at intervals. The ceramic heat sink 100 may be of a pin fin type, in which the plurality of protrusions 120 having a rhombus-shaped cross-section are formed in pin shapes or in which the plurality of protrusions 120 are provided in various pin shapes such as a cylindrical shape, a polygonal prism shape, a teardrop shape, or a diamond shape. Alternatively, as illustrated in FIG. 3, the ceramic heat sink 100 may be provided in a slit type in which a plurality of bar-shaped protrusions 120 are horizontally arranged at intervals. The shape, number, and arrangement form of the plurality of protrusions 120 may be variously changed depending on the results of previous simulations during design. The plurality of protrusions 120 may be provided to directly contact liquid coolant. Since the liquid coolant moves between the plurality of protrusions 120, the flow rate, cooling efficiency, or the like of the liquid coolant may be easily controlled as the shape, number, and arrangement form of the plurality of protrusions 120 are changed.

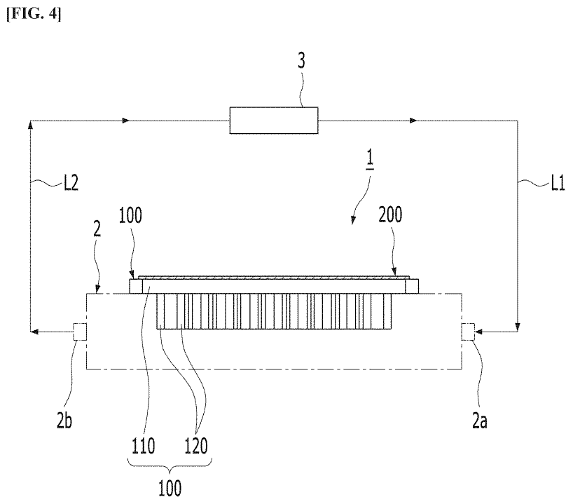

FIG. 4 is a conceptual view illustrating a configuration in which a heat sink-integrated power module substrate is mounted in a coolant circulation unit and a circulation driving unit is connected to the coolant circulation unit according to an embodiment of the present disclosure.

As illustrated in FIG. 4, a plurality of protrusions 120 may be arranged in a coolant circulation unit 2. The coolant circulation unit 2 may be provided with an inlet 2a through which liquid coolant flows in, an outlet 2b through which the liquid coolant is discharged, and an internal flow path (not illustrated) extending from the inlet 2a to the outlet 2b. Here, the liquid coolant flowing into the coolant circulation unit 2 through the inlet 2a of the coolant circulation unit 2 may be discharged through the outlet 2b via the internal flow path. Since the shape and size of the internal flow path that is a path through which the liquid coolant is moved between the inlet 2a and the outlet 2b may be designed and modified in various manners, detailed description of the internal flow path itself of the coolant circulation unit 2 will be omitted.

A circulation driving unit 3 may be connected to the coolant circulation unit 2, and may circulate the liquid coolant using the driving force of a pump (not illustrated). Here, the inlet 2a of the coolant circulation unit 2 may be connected to the circulation driving unit 3 through a first circulation line L1, and the outlet 2b of the coolant circulation unit 2 may be connected to the circulation driving unit 3 through a second circulation line L2. That is, the circulation driving unit 3 may continuously circulate the liquid coolant along a circulation path including the first circulation line L1, the coolant circulation unit 2, and the second circulation line L2. Here, the liquid coolant may be, but is not limited to, deionized water, and may be implemented using liquid nitrogen, alcohol, or other solvents as needed.

The liquid coolant supplied from the circulation driving unit 3 may flow into the inlet 2a of the coolant circulation unit 2 through the first circulation line L1, move along the internal flow path formed in the coolant circulation unit 2, and be discharged through the outlet 2b, after which the liquid coolant may move back to the circulation driving unit 3 through the second circulation line L2. Although not illustrated in detail, the circulation driving unit 3 may include a heat exchange (not illustrated). The heat exchanger of the circulation driving unit 3 may decrease the temperature of the liquid coolant, the temperature of which has increased while passing through the internal flow path of the coolant circulation unit 2, and the circulation driving unit 3 may supply the liquid coolant, the temperature of which has decreased by the heat exchanger, back to the first circulation line L1 using the driving force of the pump.

In this way, the coolant circulation unit 2 may be provided such that the liquid coolant supplied from the circulation driving unit 3 is continuously circulated. Here, the plurality of protrusions 120 may be arranged in the internal flow path of the coolant circulation unit 2, and may directly contact the liquid coolant continuously circulating along the internal flow path to perform heat exchange. That is, the plurality of protrusions 120 have a water-cooled heat dissipation structure that allows direct cooling by the continuously circulating liquid coolant to be performed.

Even if high-temperature heat is generated from a semiconductor chip (not illustrated) or the like mounted on an electrode pattern 200, the plurality of protrusions 120 are compulsorily cooled by continuously circulating liquid coolant, and thus the semiconductor chip may be maintained at a constant temperature to prevent the degradation thereof. That is, even if high-temperature heat of about 100° C. or higher is generated in the semiconductor chip, the temperature of the liquid coolant that circulates along the internal flow path of the coolant circulation unit 2 is about 25° C., and thus heat transferred to the plurality of protrusions 120 may be rapidly cooled.

In conventional technology, a ceramic substrate for a power module and a base plate for heat dissipation are separately soldered and bonded, wherein soldering paste used at this time has low thermal conductivity to reduce cooling efficiency, and a process or the like of coating Thermal Interface Materials (TIM) such as graphite needs to be additionally performed, thereby resulting in a problem in which a manufacturing process is complicated.

On the other hand, the present disclosure is advantageous in that a conductive material is screen-printed on the top surface 111 of the flat portion 110 to form a power module substrate 1, thus minimizing the process, and maximizing heat dissipation effect while implementing lightweight and small-sized structures.

The electrode pattern 200 may be generated by forming a pattern of a conductive material on the top surface 111 of the flat portion 110 and then firing the conductive material. Here, the conductive material may be conductive paste containing at least one of Ag, Cu, an Ag alloy, a Cu alloy, W, Mo, or MoW.

The pattern of the conductive material may be formed on the top surface 111 of the flat portion 110 using a screen-printing method. The screen-printing method is a method of printing the pattern of the conductive material on the top surface 111 of the flat portion 110 using a screen mask 10 so as to form an electrode that enables electrical circuit connection to Si, SiC, or GaN forming the semiconductor chip. The screen-printing method is advantageous in that printing speed is high and low process cost is required. When the electrode layer is thick, forming the electrode pattern by etching the electrode layer after the electrode layer is bonded using brazing or the like has problems including not only the requirement of a long etching time but also poor pattern precision. On the other hand, the present disclosure may skip an etching process for pattern formation by forming the electrode pattern 200 through a screen-printing method, so that the process may be minimized, the electrode pattern 200 may be precisely formed, and various patterns may be flexibly implemented. Further, since the electrode pattern 200 formed using the screen-printing method has excellent bonding strength, there are advantages in that a stable bonding state is maintained even when the electrode pattern 200 is thin, and in that wire bondability is also excellent when connection to a lead frame or the like through a wire is made.

The pattern of the conductive material, after being formed on the top surface 111 of the flat portion 110 using the screen-printing method, may be fired at a temperature ranging from 350° C. to 450° C. to enhance bonding strength. Here, it is desirable that the conductive material be a medium-temperature sintering paste that can be fired at a temperature ranging from 350° C. to 450° C. The medium-temperature sintering paste may be composed of a mixture of metal powder, binder, or the like, wherein binder enabling medium-temperature sintering may be used. For example, when Ag sintering paste is used as the conductive material, the Ag sintering paste may be sintered on the top surface 111 of the flat portion 110 made of Aluminum Nitride (AIN) in an oxidizing atmosphere. When the sintering of the Ag sintering paste is performed in the oxidizing atmosphere in this way, Al₂O₃ that is an oxide layer may be formed on the surface of AIN, thus increasing the bonding strength of a sintering layer.

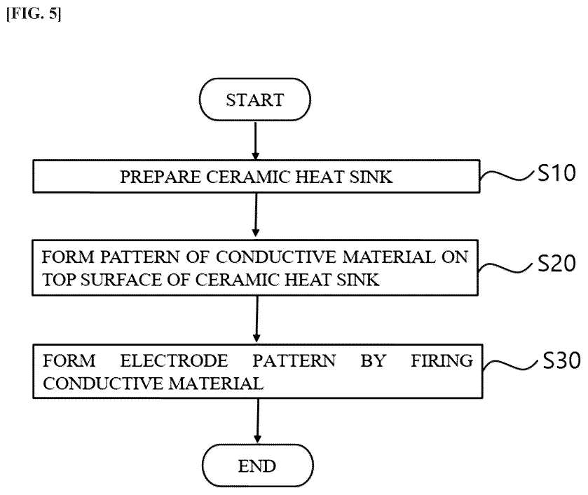

FIG. 5 is a flowchart illustrating a method of manufacturing a heat sink-integrated power module substrate according to an embodiment of the present disclosure.

As illustrated in FIG. 5, the method of manufacturing the heat sink-integrated power module substrate according to an embodiment of the present disclosure may include step S10 of preparing a ceramic heat sink 100, step S20 of forming a pattern of a conductive material on a top surface 111 of the ceramic heat sink 100, and step S30 of forming an electrode pattern 200 by firing the conductive material.

In step S10 of preparing the ceramic heat sink 100, the ceramic heat sink 100 may be formed of any one of AlN, Si₃N₄, Zirconia Toughed Alumina (ZTA), Al₂O₃, or SiC. When the ceramic heat sink 100 is formed of any one of AlN, Si₃N₄, Zirconia Toughed Alumina (ZTA), Al₂O₃, and SiC, warping hardly occurs even in a high-temperature environment of 600° C. or higher, thus enhancing heat dissipation performance. In addition, since AlN has a thermal conductivity of 150 W/m·K or more and Si₃N₄ has a thermal conductivity of 80 W/m·K or more, they may be effective in heat dissipation when used for the heat sink.

The ceramic heat sink 100 may be manufactured by any one method of injection molding (ceramic injection molding) and die casting. After the injection molding or die casting, the ceramic heat sink 100 may be manufactured through a heat treatment process and, in addition, the ceramic heat sink 100 may also be formed using a construction method such as extrusion, cutting processing, or press processing.

In step S10 of preparing the ceramic heat sink 100, the ceramic heat sink 100 may be provided with a flat portion 110 and a plurality of protrusions 120. The flat portion 110 may be a portion in which the top surface 111 directly contacts the electrode pattern 200, and may be provided in the form of a flat panel having a large area so as to facilitate heat transfer. The plurality of protrusions 120 may be formed on a bottom surface 112 of the flat portion 110 to protrude at intervals. The plurality of protrusions 120 may be arranged in an external coolant circulation unit 2 and provided to directly contact liquid coolant that circulates through the coolant circulation unit 2. The ceramic heat sink 100 may be of a pin fin type, in which the plurality of protrusions 120 having a rhombus-shaped cross-section are formed in pin shapes or in which the plurality of protrusions 120 are provided in various pin shapes such as a cylindrical shape, a polygonal prism shape, a teardrop shape, or a diamond shape. Alternatively, the ceramic heat sink 100 may be provided in a slit type in which a plurality of bar-shaped protrusions 120 are horizontally arranged at intervals.

Step S20 of forming the pattern of the conductive material on the top surface 111 of the ceramic heat sink 100 may include the step of arranging a screen mask 10 on the top surface 111 of the ceramic heat sink 100 and the step of printing the pattern of the conductive material on the top surface 111 of the ceramic heat sink 100 through the screen mask 10. In the step of printing the pattern of the conductive material, the conductive material may be conductive paste containing at least one of Ag, Cu, an Ag alloy, a Cu alloy, W, Mo, or MoW.

The method of manufacturing the heat sink-integrated power module substrate according to the embodiment of the present disclosure utilizes a screen-printing method as a method of forming the electrode pattern 200 on the flat portion 110 of the ceramic heat sink 100. The screen-printing method is a method of printing the pattern of the conductive material on the flat portion 110 of the ceramic heat sink 100 using the screen mask 10 so as to form an electrode that enables electrical circuit connection to Si, SiC, or GaN forming the semiconductor chip. The screen-printing method is advantageous in that printing speed is high and low process cost is required. When the electrode layer is thick, forming the electrode pattern by etching the electrode layer after the electrode layer is bonded using brazing or the like has problems including not only the requirement of a long etching time but also poor pattern precision. On the other hand, the present disclosure may skip an etching process for pattern formation by forming the electrode pattern 200 through the screen-printing method, so that the process may be minimized, the electrode pattern 200 may be precisely formed, and various patterns may be flexibly implemented. Further, since the electrode pattern 200 formed using the screen-printing method has excellent bonding force, there are advantages in that a stable bonding state is maintained even when the electrode pattern 200 is thin, and in that wire bondability is also excellent when connection to a lead frame or the like through a wire is made.

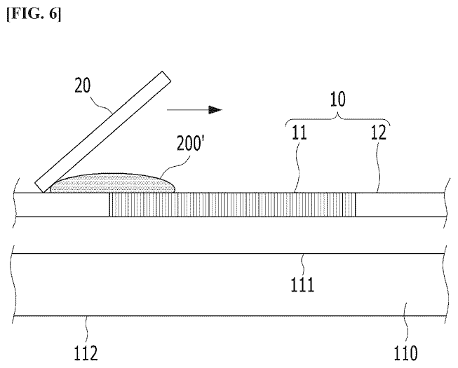

FIG. 6 is a view for describing a screen-printing process for forming an electrode pattern.

As illustrated in FIG. 6, the step of printing a pattern of a conductive material may include the step of putting conductive paste 200′ on the screen mask 10, bringing a squeegee 20 into contact with the screen mask 10, and moving the squeegee 20 on the screen mask 10. Here, the conductive paste 200′ may pass through an open pattern region 11 of the screen mask 10 and then be applied to the top surface 111 of the ceramic heat sink 100.

In the screen-printing process of the present disclosure, a screen mask having a structure in which a specific region, that is, the pattern region 11 in which the electrode pattern 200 is to be formed, is open in the form of a mesh and in which the remaining region 12 is closed may be used. The screen mask 10 may be formed of a metal material.

During screen printing, the conductive paste 200′ is put on the screen mask 10 in the state in which the screen mask 10 is arranged on the top surface 111 of the ceramic heat sink. In this state, when the squeegee 20 is brought into contact with the screen mask 10 and moved thereon, the conductive paste 200′ passes through the pattern region 11 of the screen mask 10 and does not pass through the remaining region 12, whereby the conductive paste 200′ may be applied to the top surface 111 of the ceramic heat sink 100 in a certain pattern.

The screen-printing method may implement the thicknesses of various electrode patterns 200 by suitably adjusting the mesh type and printing conditions (gap, angle, pressure, or speed) of the screen mask 10. For example, a 350 mesh or a 600 mesh formed of stainless steel may be used as the screen mask 10, and the electrode pattern 200 may be formed to have a thickness that is equal to or greater than 0.01 mm and less than or equal to 0.035 mm, but the present disclosure is not limited thereto.

Another method of forming the electrode pattern 200 on the top surface 111 of the ceramic heat sink 100 may form the electrode pattern using a thin film process or plating, but it is most desirable to form the electrode pattern using screen printing. In other words, forming the electrode pattern 200 through screen printing is advantageous in that a thickness range in which the electrode pattern 200 can be formed is wider than that of other processes and in that an etching process for pattern formation may be skipped, thus minimizing the process and forming electrodes having precise patterns.

In step S30 of forming the electrode pattern 200 by firing the conductive material, the electrode pattern 200 may be formed by firing the conductive material at a temperature ranging from 350° C. to 450° C. to enforce the bonding strength of the conductive paste 200′ applied to the top surface 111 of the ceramic heat sink 100 using the screen-printing process. Here, it is desirable that the conductive material be a medium-temperature sintering paste that can be fired at a temperature ranging from 350° C. to 450° C. The medium-temperature sintering paste may be composed of a mixture of metal powder, binder, or the like, wherein binder enabling medium-temperature sintering may be used. When the conductive material is low-temperature sintering paste, the firing temperature of the conductive material may range from 120° C. to 200° C. lower than the above-described range. Therefore, when the low-temperature sintering paste is applied to a power module in which heat of 200° C. or higher is generated from a semiconductor chip, it may be easily volatilized, thus making it difficult to apply the low-temperature sintering paste, and, in terms of cost, the low-temperature sintering paste is very expensive compared to the middle-temperature sintering paste and high-temperature sintering paste, thus decreasing production efficiency. Furthermore, when the conductive material is the high-temperature sintering paste, the firing of the conductive material is carried out at a temperature of 900° C. or higher, and thereby there are disadvantages in that oxidization of the sintering paste easily occurs and bonding strength is weak. Therefore, it is desirable that the conductive material be the medium-temperature sintering paste that can be fired at a temperature ranging from 350° C. to 450° C. When the heat treatment temperature of the medium-temperature sintering paste is below 350° C., the sintering of printed metal particles is not properly performed to increase the resistance of a completed electrode pattern, whereas when the heat treatment temperature exceeds 450° C., a shunt caused by excessive sintering occurs to decrease electrical properties.

Furthermore, in step S30 of forming the electrode pattern 200 by firing the conductive material, a firing process may be performed in an oxidizing atmosphere. Here, the oxidizing atmosphere may refer to either air atmosphere in which some oxygen is contained or atmosphere in which inactive gas, such as nitrogen or argon, is mixed with oxygen. Unlike a conventional heat sink made of metal, the heat sink-integrated power module substrate according to an embodiment of the present disclosure is configured such that the conductive material formed on the top surface of the ceramic heat sink is fired, and thus no issues attributable to oxidization happen even if a firing process proceeds in the oxidizing atmosphere. For example, when Ag sintering paste is used as the conductive material, the Ag sintering paste may be sintered on the top surface of the ceramic heat sink made of AIN in the oxidizing atmosphere, so that when sintering is performed in the oxidizing atmosphere in this way, Al₂O₃ that is an oxide layer may be formed on the surface of AlN, with the result that the bonding strength of a sintering layer may be enhanced.

The above-described heat sink-integrated power module substrate according to an embodiment of the present disclosure may be applied to the power module to ensure both multiple and large-scale connections of semiconductor chips and heat dissipation effect, and may also contribute to small-size implementation to further enhance the performance of the power module.

The above-described heat sink-integrated power module substrate according to embodiments of the present disclosure may be applied to various module components used for high power, in addition to the power module.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the scope of the claims and equivalents thereof should be construed as being included in the scope of the present disclosure.

1. A method of manufacturing a heat sink-integrated power module substrate, comprising:
preparing a ceramic heat sink;
forming a pattern of a conductive material on a top surface of the ceramic heat sink; and
forming an electrode pattern by firing the conductive material.

2. The method of claim 1, wherein the forming of the pattern of the conductive material comprises:
arranging a screen mask on the top surface of the ceramic heat sink; and
printing the pattern of the conductive material on the top surface of the ceramic heat sink through the screen mask.

3. The method of claim 2, wherein:
in the printing of the pattern of the conductive material, the conductive material is conductive paste containing at least one of Ag, Cu, an Ag alloy, a Cu alloy, W, Mo, or MoW.

4. The method of claim 3, wherein:
the printing of the pattern of the conductive material comprises:
putting the conductive paste on the screen mask, bringing a squeegee into contact with the screen mask, and moving the squeegee on the screen mask, and
in the moving,
the conductive paste is applied to the top surface of the ceramic heat sink after passing through an open pattern region of the screen mask.

5. The method of claim 4, wherein the screen mask has a structure in which the pattern region is open in a shape of a mesh and a remaining region is closed.

6. The method of claim 1, wherein the forming of the electrode pattern comprises:
forming the electrode pattern by firing the conductive material at a temperature ranging from 350° C. to 450° C.

7. The method of claim 1, wherein:
in the preparing of the ceramic heat sink,
the ceramic heat sink is manufactured using any one method of injection molding or die casting.

8. The method of claim 1, wherein:
in the preparing of the ceramic heat sink,
the ceramic heat sink comprises a flat portion in which the electrode pattern is formed on a top surface thereof and a plurality of protrusions formed on a bottom surface of the flat portion to protrude at intervals and provided to contact liquid coolant.

9. The method of claim 1, wherein:
in the preparing of the ceramic heat sink,
the ceramic heat sink is formed of any one of AlN, Si₃N₄, Zirconia Toughed Alumina (ZTA), Al₂O₃, or SiC.

10. A heat sink-integrated power module substrate, comprising:
a ceramic heat sink including a flat portion and a plurality of protrusions that are formed on a bottom surface of the flat portion to protrude at intervals and that contact liquid coolant; and
an electrode pattern formed on a top surface of the flat portion,
wherein the electrode pattern is generated by forming a pattern of a conductive material on the top surface of the flat portion and then firing the conductive material.

11. The heat sink-integrated power module substrate of claim 10, wherein:
the plurality of protrusions are arranged in an external coolant circulation unit, and
the liquid coolant circulating through the coolant circulation unit performs heat exchange with the plurality of protrusions.

12. The heat sink-integrated power module substrate of claim 10, wherein the pattern of the conductive material is formed on the top surface of the flat portion using a screen-printing method.

13. The heat sink-integrated power module substrate of claim 10, wherein the conductive material is conductive paste containing at least one of Ag, Cu, an Ag alloy, a Cu alloy, W, Mo, or MoW.

14. The heat sink-integrated power module substrate of claim 10, wherein the ceramic heat sink is manufactured using any one method of injection molding or die casting.

15. The heat sink-integrated power module substrate of claim 10, wherein the ceramic heat sink is formed of any one of AlN, Si₃N₄, Zirconia Toughed Alumina (ZTA), Al₂O₃, or SiC.
